(19) United States
(12) Patent Application Publication
(10) Pub. No.: US 2008/0057186 A1
(43) Pub. Date: Mar. 6, 2008

(54) METHOD FOR MANUFACTURING COLOR FILTERS IN IMAGE SENSOR DEVICE

(75) Inventor: Sang Sik KIM, Seoul (KR)

Correspondence Address: WORKMAN NYDEGGER, 60 EAST SOUTH TEMPLE, 1000 EAGLE GATE TOWER, SALT LAKE CITY, UT, 84111, US

(73) Assignee: DONGBU HITEK CO., LTD., Seoul (KR)

(21) Appl. No.: 11/840,791

(22) Filed: Aug. 17, 2007

(30) Foreign Application Priority Data
Aug. 31, 2006 (KR) 10-2006-0083914

(51) Int. Cl. G02B 5/23; B05D 5/06; G03F 1/00

(52) U.S. Cl. 427/167; 359/885; 430/7

(57) ABSTRACT

Provided is a method for manufacturing color filters in an image sensor device. In the method, an insulating film may first be formed on a substrate. HexaMethylDiSilazine (HMDS) gas may then be provided in a vapor state on the insulating film formed on the substrate. A surface of the insulating film may be modified to have hydrophobicity and to form silane ions thereon. The insulating film may be annealed at a second temperature greater than the first temperature. A color filter film may then be formed on the annealed insulating film with improved adherence.

### CROSS-REFERENCE TO RELATED APPLICATION

This application claims priority to Korean Application No. 10-2006-0083914, filed on Aug. 31, 2006, which is incorporated herein by reference in its entirety.

### BACKGROUND

1. Field of the Invention

Embodiments of the present invention relate to methods for manufacturing color filters in an image sensor device.

2. Description of Related Art

In recent years, semiconductor device manufacturing technology has been rapidly developing, resulting in the development and increase of semiconductor device industries.

A semiconductor device may be manufactured through a thin film forming process of forming a thin film on a silicon substrate, such as an oxide film forming process or a depositing process. Semiconductor device manufacturing processes may also include an impurity implantation process of implanting conductive impurities into the thin film, and an etching process of processing the thin film by a desired pattern, etc.

The variety of processes for manufacturing semiconductor devices, e.g., the etching process, the impurity implantation process, etc., may include a process of forming a photoresist pattern. Photoresist patterns may be used to pattern a thin film by a desired pattern and to implant impurities at a designated position.

When a conventional semiconductor device such as a transistor, a capacitor, etc. is manufactured, the photoresist pattern may be formed prior to the etching process or the impurity implantation process. Upon completion of the etching process or the impurity implantation process, the photoresist pattern is generally removed from a silicon substrate for a subsequent process.

Accordingly, when a conventional semiconductor device is manufactured, such as a transistor, a capacitor, etc., an adhesive power between the photoresist pattern and a thin film disposed under the photoresist pattern is not of much importance.

However, the adhesive power between the photoresist pattern and a thin film disposed under the photoresist pattern can be of concern in the manufacturing of other types of semiconductor devices, such as an image sensor device. An image sensor device is a type of semiconductor device that has been developed in recent years and used, for example, in digital photography applications. An image sensor device typically includes a photodiode part for receiving an incident external light and for generating a signal corresponding to the external light; a plurality of semiconductor transistors connecting with the photodiode part and for outputting the signal; a protection film covering the photodiode part and the transistors; and color filters disposed on the protection film.

The color filters disposed on the protection film may be formed by patterning a color filter film including a photosensitive material and a pigment and/or dye. The color filters are not intended to be temporarily disposed in the image sensor device, but instead are constituent elements of significance to the image sensor device.

FIG. 1 is a plane diagram of an image sensor device manufactured in accordance with the conventional art, illustrating that parts of color filters can separate from the image sensor device. In particular, FIG. 1 shows that parts of color filters 2 disposed on a protection film 1 in a matrix form have separated from the protection film 1 of the image sensor device.

A reduction of an adhesive power between the protection film 1 and the color filters 2, for example, may contribute to the separation of parts of the color filters 2 from the protection film 1 of the image sensor device.

In recent years, a technology for treating a surface of the protection film with HexaMethylDiSilazine (HMDS) gas in a vapor state has been developed to improve and prevent a reduction of an adhesive power between the protection film and the color filters.

However, a reduction of the adhesive power between the protection film and the color filters still occurs despite treatment of a surface of the protection film by HMDS gas. The reduction of the adhesive power frequently occurs particularly when the color filters include a negative photosensitive material.

Specifically, when the color filters are formed by patterning a color filter film including a negative photosensitive material, the portion of the color filter film not exposed to light is removed from the protection film and the portion of the color filter film exposed to light remains on the protection film. In other words, the portion of the color filter film exposed to light changes in physical/chemical composition and selectively remains on the protection film.

For example, among the color filters, a blue color filter has a light transmittance of merely about 5%. Therefore, when a blue color filter film including a negative photosensitive material and a blue pigment is patterned, an insufficient amount of light is transmitted to an interface portion between the blue color filter film and the protection film, although part of the blue color filter film targeting the blue color filter is exposed to light. This results in a great reduction of an adhesive power of the interface between the blue color filter film and the protection film and, consequently, increases the risk that portions of the blue color filter film will separate from the protection film, despite treatment of the surface of the protection film with HMDS gas.

### Summary of Some Example Embodiments

In general, example embodiments of the invention relate to manufacturing color filters in an image sensor device. The example embodiments may include treating, by HMDS, a surface of a thin protection film where color filters are formed and annealing a surface of the protection film treated by HMDS, thereby increasing an adhesive power between the protection film and the color filters and preventing separation of the color filters from the protection film.

In accordance with a first example embodiment a method for manufacturing color filters in an image sensor device may include forming an insulating film on a substrate where an image sensor is formed and heating the substrate at a first temperature. Next, a HexaMethylDiSilazine (HMDS) gas in a vapor state may be applied on the insulating film thereby modifying a surface of the insulating film into a state of hydrophobicity, and forming silane ions on the surface of the insulating film. Hydrothermal stability of the surface of the insulating film may then be improved by annealing the insulating film at a second temperature greater than the first temperature. Then a color filter film comprising a negative photosensitive material may be formed and combined with the silane ions on the annealed insulating film.

In accordance with another example embodiment, the method for manufacturing color filters in an image sensor device may further include applying HMDS gas in a vapor state on the insulating film after the annealing stage and before forming the color filter film on the insulating film.

Another disclosed embodiment is an image sensor device, which may include an annealed insulating film formed on a substrate where an image sensor is formed. A surface of the annealed insulating film may include silane ions that promote hydrophobicity. A color filter film comprising a negative photosensitive material may be formed on the surface of the annealed insulating film and may be combined with the silane ions.

### BRIEF DESCRIPTION OF THE DRAWINGS

Aspects of example embodiments of the invention will become apparent from the following description of example embodiments given in conjunction with the accompanying drawings, in which:

FIG. 1 is a plane diagram of an image sensor device manufactured in accordance with the conventional art, illustrating that parts of color filters can separate from the image sensor device; and

FIGS. 2 to 5 are cross-sectional diagrams illustrating a method for manufacturing color filters in an image sensor device in accordance with an exemplary embodiment.

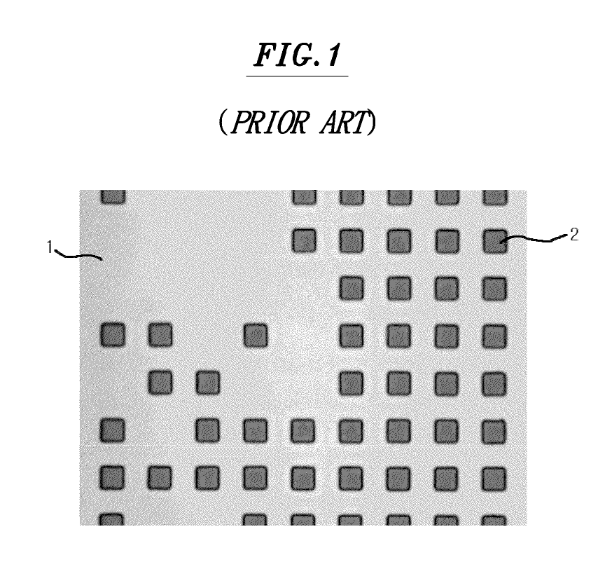

### DETAILED DESCRIPTION OF SOME EXAMPLE EMBODIMENTS

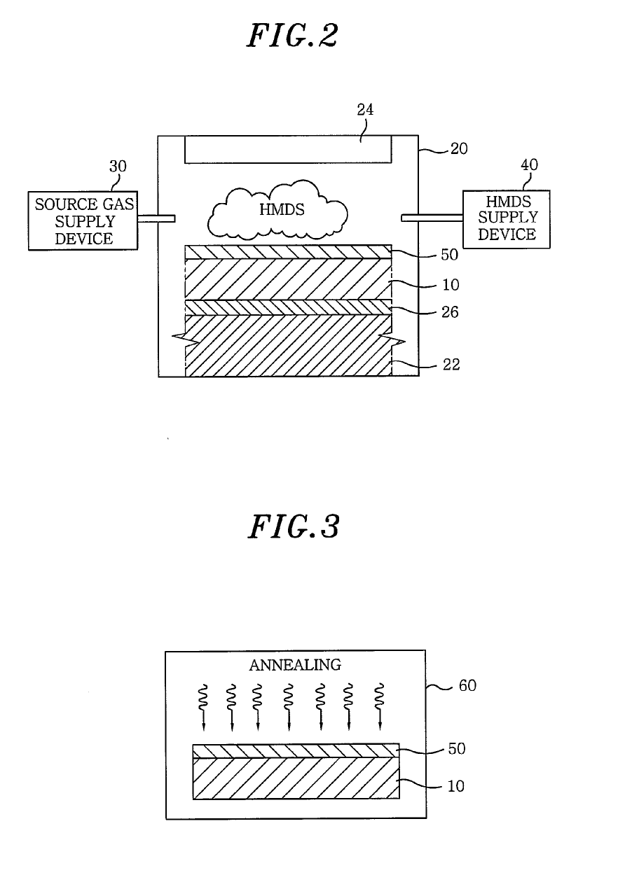

Hereinafter, aspects of example embodiments of the present invention will be described in detail with reference to the accompanying drawings so that they can be readily implemented by those skilled in the art. Referring to FIGS. 2 to 5, there are shown cross-sectional diagrams illustrating a method for manufacturing color filters in an image sensor device in accordance with an exemplary embodiment.

As shown in FIG. 2, a substrate 10 where an image sensor device (not shown) is formed, for example, a silicon substrate 10, is loaded in a chamber 20. Chamber 20 is part of equipment for forming an insulation film and treating a surface of the insulation film.

In this exemplary embodiment, the image sensor device formed over the substrate 10 includes a photodiode for collecting light and generating a signal corresponding to a level of light and a plurality of transistors for outputting the generated signal from the photodiode according to a specific timing.

In this exemplary embodiment, the chamber 20 may include a lower electrode 22, an upper electrode 24, a source gas supply device 30, and an HMDS gas supply device 40.

The lower electrode 22 may be disposed to face the upper electrode 24 within the chamber 20. A high frequency alternating current power source or a direct current power source suitable for generating plasma is provided between the lower electrode 22 and the upper electrode 24.

The source gas supply device 30 and the HMDS gas supply device 40 are connected to the chamber 20. The source gas supply device 30 provides a source gas for forming an insulating film to an inner part of the chamber 20. The HMDS gas supply device 40 provides an HMDS gas to the inner part of the chamber 20. In this exemplary embodiment, the source gas supply device 30 provides silane (SiH4) to the inner part of the chamber 20. An insulator is formed and deposited using the source gas provided from the source gas supply device 30, thereby forming an insulating film 50 on the substrate 10 disposed within the chamber 20. In this exemplary embodiment, the insulating film 50 may be Si3H4, for example.

After formation of the insulating film 50 on the substrate 10 disposed within the chamber 20, the substrate 10 may be heated to a first temperature by a heater 26 disposed on the lower electrode 22. The first temperature may preferably be within a range of about 80° C. to 150° C. Once the substrate 10 is heated to the first temperature, the HMDS gas may be provided to the inner part of the chamber 20 from the HMDS supply device 40. The HMDS gas may be provided in a vapor state. Therefore, oxide ions (—O) and hydroxide ions (—OH) may be eliminated from the insulating film 50 formed over the substrate 10. As a result, silane ions may be formed on the insulating film 50, thereby reducing the hydrophilicity of the insulating film 50 and improving hydrothermal stability.

In this exemplary embodiment, the insulating film 50 is formed on the substrate 10 and the HMDS gas is provided to the insulating film 50 within the same chamber 20. Alternatively, the process of forming the insulating film 50 on the substrate 10 and the process of providing HMDS gas to the insulating film 50 may be performed in different chambers.

Referring to FIG. 3, the substrate 10 may be annealed in an annealing chamber 60 after the insulating film 50 formed on the substrate 10 is treated by HMDS gas.

The process of annealing the substrate 10 in the annealing chamber 60 may improve an adhesive power between color filters, to be described later, and the insulating film 50.

In this exemplary embodiment, the insulating film 50 treated by HMDS gas is annealed at a second temperature greater than the first temperature to improve the adhesive power between the color filters and the insulating film 50. The second temperature suitable for improving the adhesive power between the color filters and the insulating film 50 may preferably be above about 180° C. The second temperature may more preferably be within a range of about 180° C. to 200° C. The insulating film 50 formed on the substrate 10 may be heated by a hot plate or in an oven heated at a temperature of about 180° C. to 200° C.

Although the annealing process is performed to improve the adhesive power between the color filters and the insulating film 50, further improvement may be desired. For example, in another exemplary embodiment, an insulating film 50 may be formed on a substrate 10, the insulating film 50 may be treated by HMDS gas, and the insulating film 50 may be annealed at a temperature of about 180° C. to 200° C., as described above. Then the insulating film 50 can be treated a second time with HMDS gas to further improve an adhesive power between the insulating film 50 and color filters.

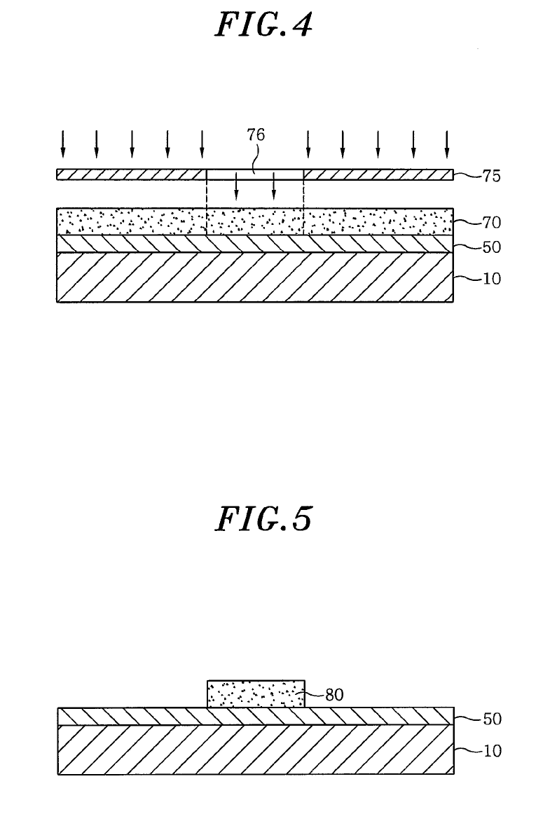

Referring to FIG. 4, a color filter film 70 may be formed on the insulating film 50 after the insulating film 50 formed on the substrate 10 is annealed at the temperature of about 180° C. to 200° C.

In this exemplary embodiment, the color filter film 70 may include a negative photosensitive substance, a solvent, and a pigment for expressing color. In this exemplary embodiment, the color filter film 70 can be formed in a spin coating process, for example.

After the forming of the color filter film 70, the color filter film 70 may be treated with HMDS gas to more strongly adhere to a surface of the insulating film 50 annealed at a temperature of about 180° C. to 200° C.

The adhesive power between the insulating film 50 treated by HMDS gas and annealed at a temperature of about 180° C. to 200° C. and the color filter film 70 is greater than an adhesive power between an insulating film 50 treated merely by HMDS gas and a color filter film 70.

A mask 75 may be disposed on the color filter film 70 after the color filter film 70 is formed on the insulating film 50 treated with HMDS gas and annealed at a temperature of about 180° C. to 200° C. In this exemplary embodiment, an opening 76 is provided at part of the mask 75 where a color filter is to be formed.

Referring to FIG. 5, light is projected toward the color filter film 70 disposed on the insulating film 50 from a top of the mask 75. Thus, light passing through the opening 76 of the mask 75 is projected on to the color filter film 70.

After that, a development process may be performed. By doing so, the color filter film 70 exposed to light remains on the insulating film 50 and the color filter film 70 not exposed to light is removed from the insulating film 50. Thus, a color filter 80 is formed on the insulating film 50.

When the color filter 80 has a low transmittance, an amount of light provided to an interface portion between the color filter 80 and the insulating film 50 may be insufficient and thus, the adhesive power between the color filter 80 and the insulating film 50 may be relatively weak. However, this can be overcome by, among other things, treating the insulating film 50 by HMDS gas and annealing the insulating film 50 at a temperature of about 180° C. to 200° C.

As in detail described above, an insulating film may be first treated by HMDS gas and then, the treated insulating film may be annealed, thereby improving an adhesive power between the insulating film and the color filter disposed on the insulating film. Accordingly, the color filter is less likely to separate from the insulating film.

While the invention has been shown and described with respect to the preferred embodiments, it will be understood by those skilled in the art that various changes and modifications may be made without departing from the scope of the invention as defined in the following claims.

What is claimed is:

1. A method for manufacturing color filters suitable for use in an image sensor device, which comprises:
forming an insulating film on a substrate;
heating the substrate at a first temperature;
applying HexaMethylDiSilazine (HMDS) gas in a vapor state on the insulating film formed on the substrate and forming silane ions on the surface of the insulating film;
annealing the insulating film at a second temperature greater than the first temperature; and
forming a color filter film that combines with the silane ions on the annealed insulating film, the color filter film comprising a negative photosensitive material.

2. The method of claim 1, wherein the insulating film is treated with HMDS gas after annealing at the second temperature.

3. The method of claim 2, wherein the first temperature is within a range of about 80° C. to 150° C.

4. The method of claim 3, wherein the second temperature is above about 180° C.

5. The method of claim 4, wherein the color filter film comprising a negative photosensitive material is treated with HMDS gas.

6. The method of claim 5, wherein the insulating film is formed using a source gas on the substrate.

7. The method of claim 6, wherein the source gas is silane.

8. A method for manufacturing color filters in an image sensor device, which comprises:
forming an insulating film on a substrate where an image sensor is formed;
heating the substrate at a first temperature;
applying HexaMethylDiSilazine (HMDS) gas in a vapor state on the insulating film formed on the substrate thereby modifying a surface of the insulating film into a state of hydrophobicity and forming silane ions on the surface of the insulating film;
annealing the insulating film at a second temperature greater than the first temperature to improve hydrothermal stability of the surface of the insulating film where the silane ions are formed;
applying HMDS gas in a vapor state on the annealed insulating film; and
forming a color filter film that combines with the silane ions on the annealed insulating film, the color filter film comprising a negative photosensitive material.

9. The method of claim 8, wherein the first temperature is within a range of about 80° C. to 150° C.

10. The method of claim 9, wherein the second temperature is above about 180° C.

11. The method of claim 10, wherein the color filter film comprising a negative photosensitive material is treated with HMDS gas.

12. The method of claim 11, wherein the insulating film is formed by applying a source gas on the substrate.

13. The method of claim 12, wherein the source gas is silane.

14. An image sensor device, which comprises:
an annealed insulating film formed on a substrate where an image sensor is formed, wherein a surface of the annealed insulating film includes silane ions that promote hydrophobicity; and
a color filter film formed on the surface of the annealed insulating film and combined with the silane ions, the color filter film comprising a negative photosensitive material.
